(19) United States
(12) Patent Application Publication
(10) Pub. No.: US 2023/0394195 A1
(43) Pub. Date: Dec. 7, 2023

(54) ESTIMATION MODEL GENERATION DEVICE AND TOOL LIFETIME ESTIMATION DEVICE

(71) Applicant: Panasonic Intellectual Property Management Co., Ltd., Osaka (JP)

(72) Inventors: Mitsuo SAITOH, Osaka (JP); Naoki NOJIRI, Osaka (JP); Hideaki HAMADA, Hyogo (JP); Taihei OKADA, Hyogo (JP)

(21) Appl. No.: 18/235,409

(22) Filed: Aug. 18, 2023

Related U.S. Application Data
(63) Continuation of application No. PCT/JP2022/000131, filed on Jan. 5, 2022.

(30) Foreign Application Priority Data
Feb. 26, 2021 (JP) 2021-029932

(51) Int. Cl. G06F 30/20

(52) U.S. Cl. CPC G06F 30/20

(57) ABSTRACT

Provided is an estimation model generation device configured to generate an estimation model for estimating a lifetime of a tool based on a load curve indicating temporal change or positional change of the load applied to the tool, the tool being used for repeatedly machining a plurality of workpieces in a plate-shape while applying the load to each of the plurality of workpieces, the estimation model generation device including: an information acquisition unit that acquires the load curve at a timing before the tool reaches the end of lifetime due to repeated machining using the tool; an estimation model generation unit that generates, based on load data and a tool lifetime, an estimation model for predicting the lifetime of the tool, the load data being obtained by separating the load curve into a first load curve and a second load curve.

### TECHNICAL FIELD

The present disclosure relates to an estimation model generation device and a tool lifetime estimation device.

### BACKGROUND ART

Tools used in machine tools deteriorate in machining accuracy of a workpiece due to wear caused by repeated use. When a tool cannot maintain its predetermined machining accuracy, the tool reaches its lifetime. To grasp the lifetime of a tool and take measures such as replacing the tool with a new tool before the tool reaches its lifetime, a technique for estimating a lifetime of a tool has been studied.

PTL 1 discloses a tool lifetime estimation device that constructs a learning model by unsupervised learning using machining information indicating a machining status as input data and that estimates a tool lifetime using the learning model.

### CITATION LIST

### Patent Literature

PTL 1: Japanese Patent No. 6404893

### SUMMARY OF THE INVENTION

An estimation model generation device according to an aspect of the present disclosure generates an estimation model for estimating a lifetime of a tool based on a load curve indicating temporal change or positional change of the load applied to the tool, the tool being used for repeatedly machining multiple workpieces in a plate-shape while applying a load to each workpiece. The estimation model generation device includes an information acquisition unit that acquires the load curve at a timing before the tool reaches a lifetime due to repeated machining using the tool, an estimation model generation unit that generates, based on load data and a tool lifetime, an estimation model for predicting the lifetime of the tool, the load data being obtained by separating the load curve into a first load curve and a second load curve, the tool lifetime being a time period from time of acquiring the load curve to time at which the tool reaches the lifetime, and a storage unit that stores the estimation model. The first load curve is acquired when the workpiece is deformed due to machining with the tool, and the second load curve is acquired immediately after the workpiece is deformed due to machining with the tool.

### BRIEF DESCRIPTION OF THE DRAWINGS

FIG. 1A is a block diagram illustrating an estimation model generation device according to a first exemplary embodiment.

FIG. 1B is a block diagram illustrating a tool lifetime estimation device according to the first exemplary embodiment.

FIG. 1C is a block diagram illustrating a machining device.

FIG. 2A is a schematic diagram illustrating a step of punching a workpiece with a machining device.

FIG. 2B is a schematic diagram illustrating the step of punching the workpiece with the machining device.

FIG. 2C is a schematic diagram illustrating a step of punching a workpiece with a machining device.

FIG. 2D is a schematic diagram illustrating the step of punching the workpiece with the machining device.

FIG. 3 is a graph illustrating temporal change of a load applied to a punch during punching with the machining device.

FIG. 4A is a graph illustrating a load curve at a 100-th shot from a start of using a punch.

FIG. 4B is a graph illustrating a load curve at a 200,000-th shot from the start of using the punch.

FIG. 5 is a diagram illustrating a load curve acquired by an information acquisition unit of the estimation model generation device.

FIG. 6 is a graph illustrating an estimation model.

FIG. 7 is a diagram illustrating a load curve acquired by an information acquisition unit of the tool lifetime estimation device.

FIG. 8 is a graph in which points indicating maximum loads acquired during machining and the number of shots at the respective points are plotted in the estimation model of FIG. 6.

FIG. 9 is a diagram illustrating a load curve acquired by an information acquisition unit of an estimation model generation device according to a second exemplary embodiment.

FIG. 10 is a graph illustrating a tendency of maximum loads applied to a punch and a tendency of integral values (load energy) of a load curve.

FIG. 11 is a diagram illustrating a load curve acquired by an information acquisition unit of an estimation model generation device according to a third exemplary embodiment.

FIG. 12 is a graph illustrating a tendency of integral values of load energy of the entire load curve, and a tendency of integral values of load energy of each of a first load curve and a second load curve.

FIG. 13 is a graph illustrating a relationship between a load curve and the number of shots.

FIG. 14 is a graph illustrating estimation of a tool lifetime using the graph of FIG. 13.

### DESCRIPTION OF EMBODIMENT

### Background to Present Disclosure

Repeating machining causes tools used in machine tools to be worn, so that predetermined machining accuracy cannot be maintained. Each tool unable to maintain its predetermined machining accuracy is determined to reach the end of its tool lifetime, and replacement with a new tool, polishing of the tool, or the like is performed.

A tool lifetime is conventionally determined based on a size of a burr appearing in a product shape obtained by machining. Unfortunately, this determination causes a problem in that a defective product is continuously produced by a tool having reached its lifetime until a size of a burr is measured.

Thus, as in the tool lifetime estimation device disclosed in PTL 1, a method for constructing a learning model using machining information indicating a machining status as input data to estimate a lifetime of a tool from machining information using the learning model has been studied. However, the tool lifetime estimation device described in PTL 1 still has room for improvement in terms of improvement in lifetime prediction accuracy.

The present inventors have found that a tool lifetime can be estimated with higher accuracy by constructing an estimation model using information on a load applied to a tool instead of information on machining as described in PTL 1, and using the estimation model, and then having made the following invention. The present disclosure provides an estimation model generation device and a tool lifetime estimation device that are improved in prediction accuracy of a tool lifetime.

An estimation model generation device according to an aspect of the present disclosure generates an estimation model for estimating a lifetime of a tool based on a load curve indicating temporal change or positional change of the load applied to the tool, the tool being used for repeatedly machining multiple workpieces in a plate-shape while applying a load to each workpiece. The estimation model generation device includes an information acquisition unit that acquires the load curve at a timing before the tool reaches a lifetime due to repeated machining using the tool, an estimation model generation unit that generates, based on load data and a tool lifetime, an estimation model for predicting the lifetime of the tool, the load data being obtained by separating the load curve into a first load curve and a second load curve, the tool lifetime being a time period from time of acquiring the load curve to time at which the tool reaches the lifetime, and a storage unit that stores the estimation model. The first load curve is acquired when the workpiece is deformed due to machining with the tool, and the second load curve is acquired immediately after the workpiece is deformed due to machining with the tool.

Such a configuration enables providing an estimation model generation device improved in prediction accuracy of a tool lifetime.

The load data may be generated based on an integral value of the first load curve and an integral value of the second load curve.

Such a configuration enables generating an estimation model using load energy or an impulse on the tool, so that the lifetime prediction accuracy can be further improved.

The estimation model generation unit may generate the estimation model by performing machine learning using teacher data in which the load data as an explanatory variable is associated with the tool lifetime as a target variable.

Such a configuration enables further improving the lifetime prediction accuracy.

The estimation model generation unit may generate the estimation model using the load data acquired by weighting the first load curve and the second load curve.

Such a configuration enables performing the lifetime prediction with high accuracy even when the tendency of the load energy on the tool varies depending on a material of the workpiece or a type of a mold.

The first load curve and the second load curve may be weighted by multiplying the first load curve and the second load curve by a predetermined coefficient.

Such a configuration enables performing the lifetime prediction with high accuracy by weighting the first load curve and the second load curve.

The load curve may indicate a relationship between a load applied to the tool and time.

Such a configuration enables generating an estimation model using the load energy applied to the tool, so that prediction accuracy can be improved.

The load curve may indicate a relationship between a load applied to the tool and a travel distance of the tool.

Such a configuration enables generating an estimation model using an impulse applied to a tool, so that the prediction accuracy can be improved.

A tool lifetime estimation device according to an aspect of the present disclosure generates an estimation model for estimating a lifetime of a tool based on a load curve indicating temporal change or positional change of the load applied to the tool, the tool being used for repeatedly machining multiple workpieces in a plate-shape while applying a load to each workpiece. The tool lifetime estimation device includes a storage unit that stores an estimation model generated by any one of the above-described estimation model generation devices, an information acquisition unit that acquire a load curve during machining with the tool, and a load data generator that generates load data in which the load curve during machining is separated into a first load curve and a second load curve, and an estimation unit that estimates the tool lifetime from the load data based on the estimation model. The first load curve is acquired when the workpiece is deformed due to machining with the tool, and the second load curve is acquired immediately after the workpiece is deformed due to machining with the tool.

Such a configuration enables providing tool lifetime estimation device improved in prediction accuracy of a tool lifetime.

The load data may be generated based on an integral value of the first load curve and an integral value of the second load curve.

Such a configuration enables further improvement in prediction accuracy.

Exemplary embodiments of the present disclosure will be described in detail below with reference to the drawings as appropriate. Unnecessary detailed description may not be described. For example, detailed description of well-known matters and repeated description of a substantially identical configuration may not be described. This is to avoid an unnecessarily redundant description below and to facilitate understanding of a person skilled in the art. The inventors provide the attached drawings and the following description for a person skilled in the art to fully understand the present disclosure, and do not intend to limit the subject matter described in the scope of claims with the drawings and the description.

### First Exemplary Embodiment

[General Configuration]

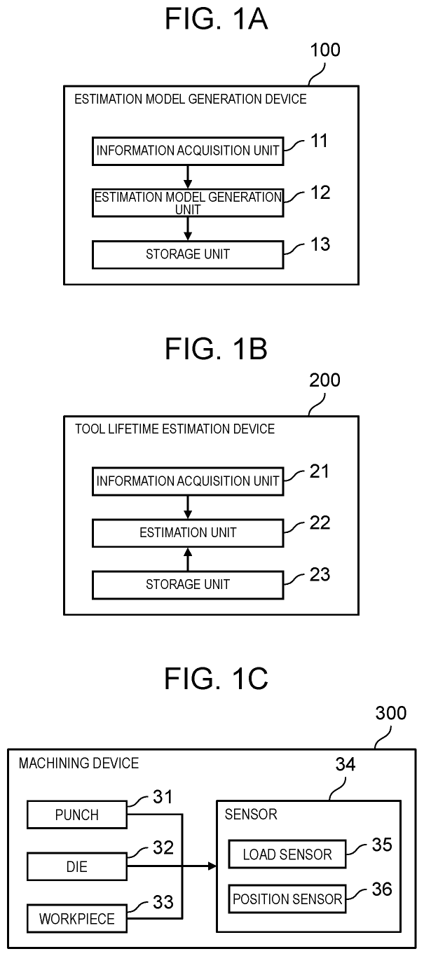

FIG. 1A is a block diagram illustrating estimation model generation device 100 according to a first exemplary embodiment. FIG. 1B is a block diagram illustrating tool lifetime estimation device 200 according to the first exemplary embodiment. FIG. 1C is a block diagram illustrating machining device 300. Each device may be installed in an identical factory or in two or more sites. Estimation model generation device 100 and tool lifetime estimation device 200 may be integrated.

With reference to FIGS. 1A to 1C, estimation model generation device 100 and tool lifetime estimation device 200 according to the present exemplary embodiment will be described. Estimation model generation device 100, tool lifetime estimation device 200, and machining device 300 are connected to one another in a transmissible manner by wired or wireless connection. Communication can be performed using a public line such as the Internet and/or a dedicated line.

Estimation model generation device 100 illustrated in FIG. 1A generates an estimation model for predicting a lifetime of a tool used in machining device 300 based on a load curve acquired during machining of machining device 300 illustrated in FIG. 1C. Estimation model generation device 100 can be constructed using a computer system such as a PC or a workstation, for example. Estimation model generation device 100 includes information acquisition unit 11, estimation model generation unit 12, and storage unit 13.

Information acquisition unit 11 acquires a load curve until repeated machining using a tool of the machining device causes the tool to reach its lifetime. The load curve is determined based on a result detected by sensor 34 of machining device 300 described later.

Estimation model generation unit 12 generates an estimation model for predicting a tool lifetime based on the load curve and a tool lifetime from acquisition time of the load curve to the lifetime. The tool lifetime will be described later.

Storage unit 13 stores an estimation model generated by estimation model generation unit 12.

Tool lifetime estimation device 200 illustrated in FIG. 1B estimates a lifetime of a tool of machining device 300 from the load curve of machining device 300 based on the estimation model generated by estimation model generation device 100 of FIG. 1A. Tool lifetime estimation device 200 may be composed of a microcomputer, a central processing unit (CPU), a microprocessor unit (MPU), a graphics processor unit (GPU), a digital signal processor (DSP), a field-programmable gate array (FPGA), or an application specific integrated circuit (ASIC), for example. Tool lifetime estimation device 200 has a function that may be implemented only by hardware or may be implemented by a combination of hardware and software. Tool lifetime estimation device 200 includes an information acquisition unit 21, estimation unit 22, and storage unit 23.

Information acquisition unit 21 acquires a load curve during machining with machining device 300.

Storage unit 23 stores an estimation model generated by estimation model generation device 100.

Estimation unit 22 estimates a tool lifetime from the load curve during machining based on the estimation model.

Machining device 300 illustrated in FIG. 1C repeatedly machines multiple workpieces that are each a plate-shaped metal while applying a load to each workpiece. Machining device 300 according to the present exemplary embodiment will be described as a press machining device that includes punch 31 and die 32 and machines workpiece 33 with punch 31 and die 32.

Machining device 300 includes die 32 and punch 31 facing die 32, and machines workpiece 33 disposed in die 32 with a load of punch 31.

Machining device 300 includes sensor 34 disposed to acquire a load on punch 31 and a travel distance of punch 31. As sensor 34, load sensor 35, position sensor 36, and the like are used, for example.

Load sensor 35 preferably has high sensitivity to detect a minute change in load on punch 31. Thus, a quartz piezoelectric sensor is suitable as load sensor 35.

Position sensor 36 preferably has high resolution to detect a minute change in position (travel distance) of punch 31. Thus, an eddy current sensor or a capacitance sensor is suitable as position sensor 36.

<Estimation Model Generation Device>

Estimation model generation device 100 generates an estimation model for estimating a lifetime of a tool that repeatedly machines workpiece 33 while applying a load to workpiece 33 in a plate-shape based on a load curve indicating temporal change or positional change of the load applied to the tool.

A lifetime of a tool indicates tool wear or damage caused by repeated machining of multiple workpieces 33 using the tools (punch 31 and die 32) of machining device 300. When repeated machining causes a predetermined product shape to be unable to be maintained due to wear of the tool or the predetermined product shape to be unable to be maintained due to damage of the tool, the tool is determined to reach its lifetime, and the tool is then ground again or replaced.

Estimation model generation device 100 in the present exemplary embodiment generates an estimation model based on a load curve indicating temporal change of a load applied to a tool, particularly of a load applied to punch 31.

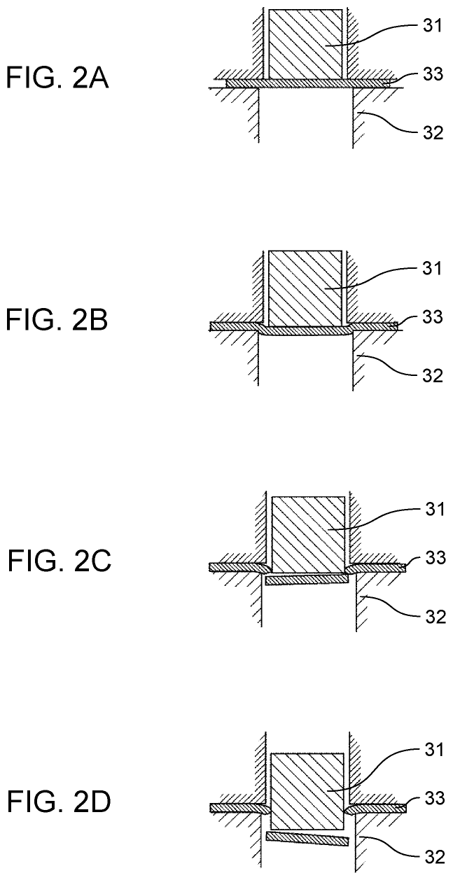

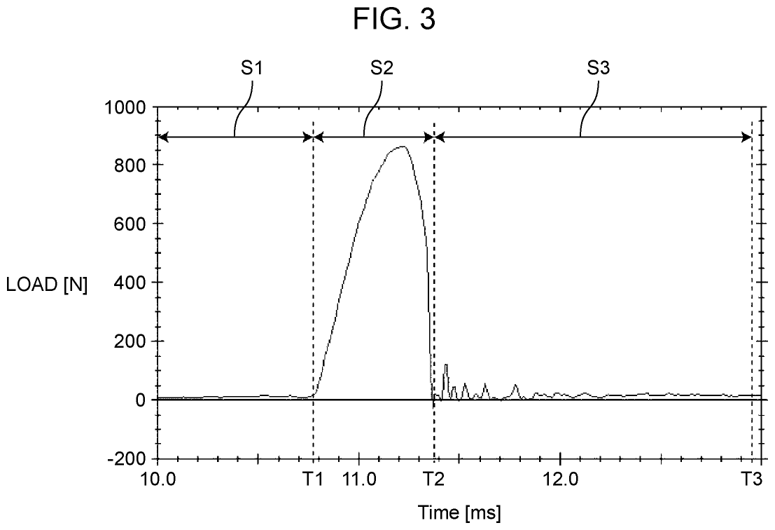

The load curve indicates temporal change or positional change of the load applied to the punch acquired by load sensor 35. Here, the load curve indicating a relationship between the load and time will be described with reference to FIGS. 2A to 3.

FIGS. 2A to 2D are schematic views illustrating respective steps of punching workpiece 33 with machining device 300. FIG. 3 is a graph illustrating temporal change of a load applied to punch 31 during punching with machining device 300.

When machining is started, punch 31 descends and punch 31 comes into contact with workpiece 33 (FIG. 2A). The graph of FIG. 3 indicates time T1 at which punch 31 comes into contact with workpiece 33. As illustrated in the graph of FIG. 3, almost no load is applied to punch 31 until punch 31 comes into contact with workpiece 33 (section S1 in FIG. 3).

When punch 31 starts punching workpiece 33 (FIG. 2B), a load on punch 31 rapidly increases as illustrated in section S2 of the graph of FIG. 3. The graph of FIG. 3 indicates time T2 at which workpiece 33 is cut by punch 31 (FIG. 2C). When workpiece 33 is cut, the load applied to punch 31 decreases to near zero. This is because resistance to punch 31 is eliminated by punching workpiece 33. Even when workpiece 33 is cut, the load applied to punch 31 detected by sensor 34 may not reach zero due to vibration of the punch or other external factors. In this case, a load at the lowest dead center after a peak of the load rapidly increasing during punching is desirably to be the load after punching of workpiece 33. Similar factors may cause the load applied to punch 31 detected by sensor 34 to measure zero multiple times. In this case, the load of zero any time when may be set as the load after punching of workpiece 33, and the load of zero at the first time is desirably set as the load after punching of workpiece 33.

For a while after workpiece 33 is punched out (section S3 of the graph of FIG. 3), a load is applied to punch 31 due to interference between punch 31 and die 32, a disturbance element caused by a material, or the like. For example, inclination of punch 31 and die 32 may cause punch 31 and die 32 to come into contact with each other to apply a load to punch 31. Alternatively, workpiece 33 after cutting may be drawn between punch 31 and die 32 (FIG. 2D) to apply a load to punch 31.

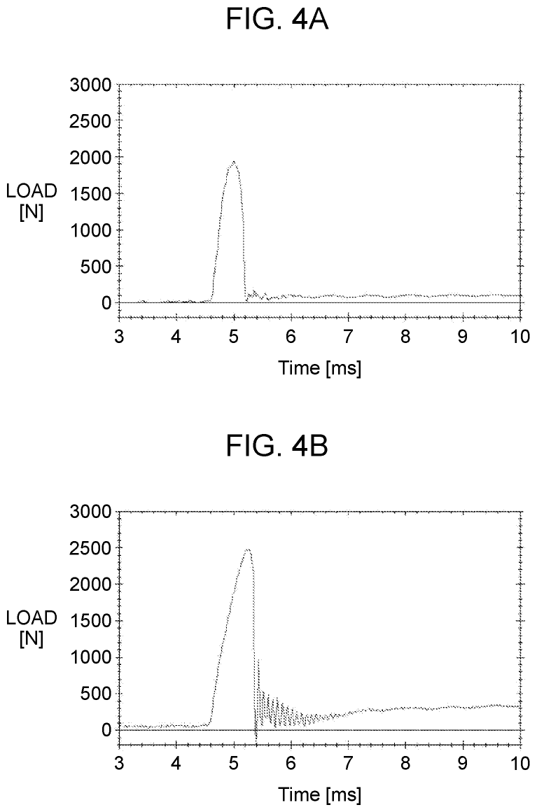

When repeated machining causes punch 31 to be worn, the load applied to punch 31 during the machining increases. FIG. 4A is a graph illustrating a load curve at a 100-th shot from a start of using punch 31. FIG. 4B is a graph illustrating a load curve at a 200,000-th shot from the start of using punch 31. As illustrated in FIGS. 4A and 4B, repeated machining causes the maximum load during punching to increase. This is because the repeated machining causes punch 31 to be worn, and thus applying a larger load to punch 31. Additionally, the load after punching is also increased. This is because burrs increase in number due to the wear of punch 31 and interfere with punch 31, so that a load applied to punch 31 increases.

The description above reveals that the load curve and progress of wear of the tool (punch 31) are closely related. Thus, estimation model generation unit 12 of estimation model generation device 100 in the present exemplary embodiment generates an estimation model for predicting a tool lifetime based on the load curve and a tool lifetime at that time.

The load curve is acquired by information acquisition unit 11 of estimation model generation device 100 based on the load applied to punch 31 and detected by sensor 34 of the machining device 300.

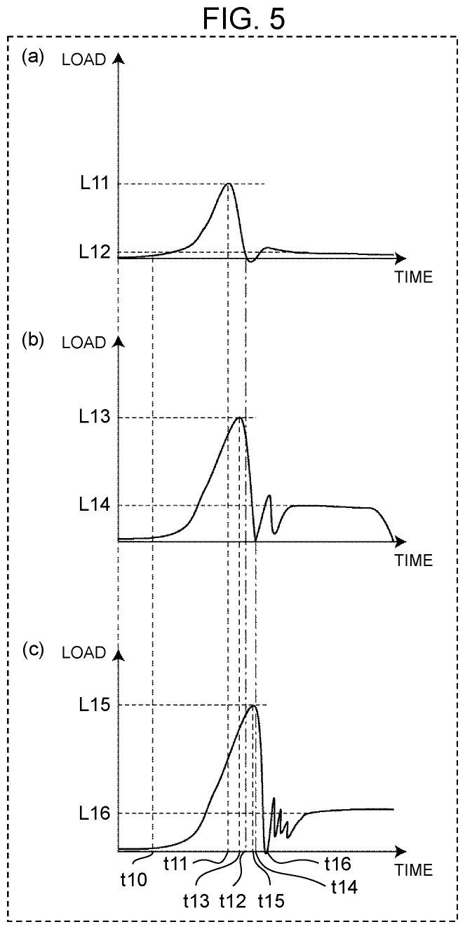

FIG. 5 is a diagram illustrating a load curve acquired by information acquisition unit 11 of estimation model generation device 100. Each load curve in FIG. 5 indicates a relationship between the load applied to punch 31 and time. Part (a) of FIG. 5 shows a load curve obtained at the 100,000-th shot. Part (b) of FIG. 5 shows a load curve obtained at the 200,000-th shot. Part (c) of FIG. 5 shows a load curve obtained at the 300,000-th shot.

Information acquisition unit 11 acquires load curves as illustrated in parts (a) to (c) of FIG. 5 based on detection values of sensor 34. The load curve may be obtained for every shot until punch 31 reaches its lifetime or may be obtained at predetermined time intervals.

Estimation model generation unit 12 generates an estimation model based on the load curve acquired by information acquisition unit 11 and a tool lifetime from acquisition time of the load curve to the lifetime. For example, an estimation model can be generated based on maximum loads of acquired load curves including those of parts (a) to (c) of FIG. 5.

The load curve of part (a) of FIG. 5 shows a maximum load of L11, and a load of L12 to which the load after punching converges. Similarly, the load curve of part (b) of FIG. 5 shows a maximum load of L13, and a load of L14 to which the load after punching converges. Part (c) of FIG. 5 shows a maximum load of L15, and a load of L16 to which the load after punching converges. In this way, the maximum load is calculated in every load curve acquired and every load curve is associated with the number of shots at the time when the load curve is acquired. At this time, a load curve when an abnormality such as breakage of a tool occurs, for example, may be excluded.

Parts (a) to (c) of FIG. 5 reveals that the maximum load increases as the number of shots increases. That is, a maximum magnitude of load for each number of shots has a relationship of L11<L13<L15. Similarly, as the number of shots increases, the load after punching also increases. That is, a magnitude of the load after punching for each number of shots has a relationship of L12<L14<L16. This is because as the number of shots increases, the wear of punch 31 progresses and the amount of material drawn increases, and thus increasing the amount of interference between punch 31 and workpiece 33.

The load curves of parts (a) to (c) of FIG. 5 each show time t10 at which punch 31 comes into contact with workpiece 33. The load curve of part (a) of FIG. 5 shows time t11 with maximum load L11, and time t12 at which workpiece 33 is cut. The load curve of part (b) of FIG. 5 similarly shows time t13 with maximum load L13, and time t14 at which workpiece 33 is cut. The load curve of part (c) of FIG. 5 also shows time t15 with maximum load L15, and time t16 at which workpiece 33 is cut.

Here, comparison among the times indicating the maximum loads at the respective numbers of shots shows a relationship of t11<t13<t15. This is because progress in wear of punch 31 with increase in the number of shots causes progress of cracks in workpiece 33 to take time. Then, comparison among the times at each of which workpiece 33 is completely cut at the respective numbers of shots shows a relationship of t12<t14<t16. This is because the progress in wear of punch 31 with increase in the number of shots causes time to be taken to complete cutting of workpiece 33. That is, the progress in wear of punch 31 causes workpiece 33 to gradually shift from a shear mode to a mode of extending fully. Additionally, comparison between times each showing a maximum load and times at each of which workpiece 33 is cut shows a relationship satisfying (t12−t11)<(t14−t13)<(t16−T15). This is because the mode of extending fully takes time longer for cutting than the shear mode, and thus the progress of wear of punch 31 increases time until the material is completely cut.

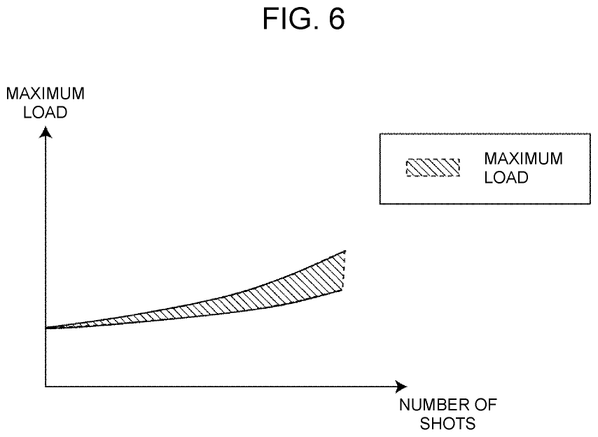

FIG. 6 is a graph illustrating an estimation model. FIG. 6 is a graph illustrating an estimation model. When punch 31 has a tool lifetime of 500,000 shots, an estimation model of 500,000 shots, or of maximum loads until punch 31 reaches the lifetime is shown.

For data in which the maximum load of the load curve until punch 31 reaches the lifetime and the number of shots are associated with each other as illustrated in each of parts (a) to (c) of FIG. 5, a graph as illustrated in FIG. 6 can be generated as a time series trend graph. Alternatively, applying a regression analysis method such as an autoregressive integrated moving average (ARIMA) or a seasonal autoregressive integrated moving average (SARIMA) model, for example, enables generating not only a graph representing transition of time series as with FIG. 6, but also a graph for estimating predictive values of the time series. FIG. 6 shows that increase in the number of shots increases variation. This is because the variation in the load curve increases as punch 31 approaches the tool lifetime.

<Tool Lifetime Estimation Device>

Tool lifetime estimation device 200 estimates a lifetime of a tool (punch 31) of machining device 300 based on the estimation model of FIG. 6.

Storage unit 23 stores an estimation model generated by estimation model generation device 100.

Information acquisition unit 21 acquires a load curve for punch 31 during machining with machining device 300. The load curve is obtained based on detection values from sensor 34 of machining device 300.

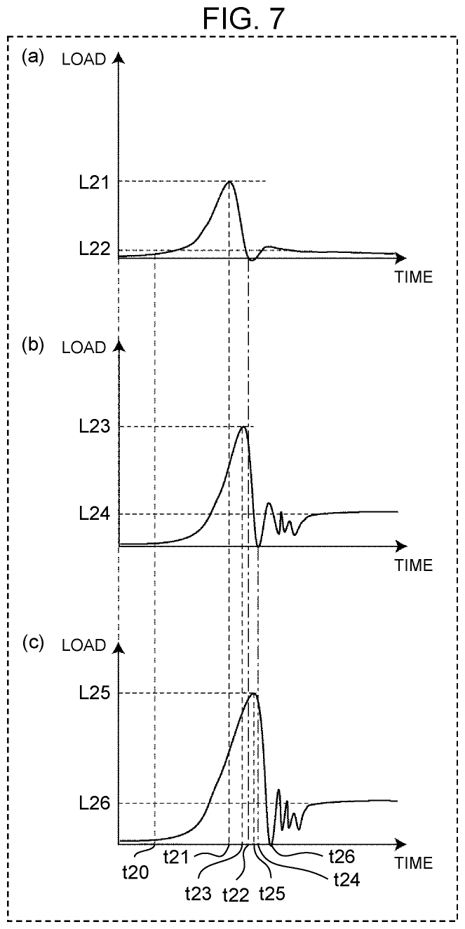

FIG. 7 is a diagram illustrating a load curve acquired by information acquisition unit 21 of tool lifetime estimation device 200. Part (a) of FIG. 7 shows a load curve obtained at the 100,000-th shot. Part (b) of FIG. 7 shows a load curve obtained at the 200,000-th shot. Part (c) of FIG. 7 shows a load curve obtained at the 300,000-th shot.

The load curve of part (a) of FIG. 7 shows a maximum load of L21, and a load of L22 to which the load after punching converges. Similarly, the load curve of part (b) of FIG. 7 shows a maximum load of L23, and a load of L24 to which the load after punching converges. Part (c) of FIG. 7 shows a maximum load of L25, and a load of L26 to which the load after punching converges.

The load curves of parts (a) to (c) of FIG. 7 each show time t20 at which punch 31 comes into contact with workpiece 33. The load curve of part (a) of FIG. 7 shows time t21 with maximum load L21, and time t22 at which workpiece 33 is cut. The load curve of part (b) of FIG. 5 similarly shows time t23 with maximum load L23, and time t24 at which workpiece 33 is cut. The load curve of part (c) of FIG. 7 also shows time t25 with maximum load L25, and time t26 at which workpiece 33 is cut.

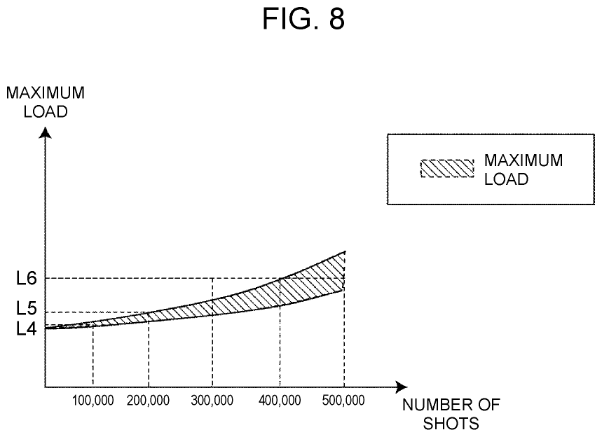

Estimation unit 22 estimates a tool lifetime from the load curve for punch 31 during machining based on the estimation model generated by estimation model generation device 100. FIG. 8 is a graph in which points indicating maximum loads acquired during machining and the number of shots at the respective points are plotted in the estimation model of FIG. 6.

Estimation unit 22 predicts the number of shots until punch 31 reaches the lifetime from a load of punch 31 and the number of shots thereof during machining. For example, the graph of FIG. 8 shows that maximum loads at 100,000-th and 200,000-th shots are within a range of the estimation model. In contrast, a maximum load at a 300,000-th shot exceeds the maximum load indicated by the estimation model of a maximum load. Thus, estimation unit 22 estimates that punch 31 during current machining reaches the tool lifetime earlier than 500,000 shots of the tool lifetime when the estimation model is generated.

[Effects]

The exemplary embodiment described above enables providing an estimation model generation device and a tool lifetime estimation device that are improved in prediction accuracy of a tool lifetime.

Although the estimation model is generated using the load curve indicating the relationship between the load applied to the tool (punch 31) and time in the exemplary embodiment described above, the load curve may indicate a relationship between the load applied to the tool and a travel distance of the tool.

Additionally, although an example is described in the exemplary embodiment described above, in which machining device 300 is a press machining device that performs punching, the machining device is not limited to such a press machining device. For example, the machining device may perform bending or drawing. Alternatively, the machining device may perform shear cutting.

### Second Exemplary Embodiment

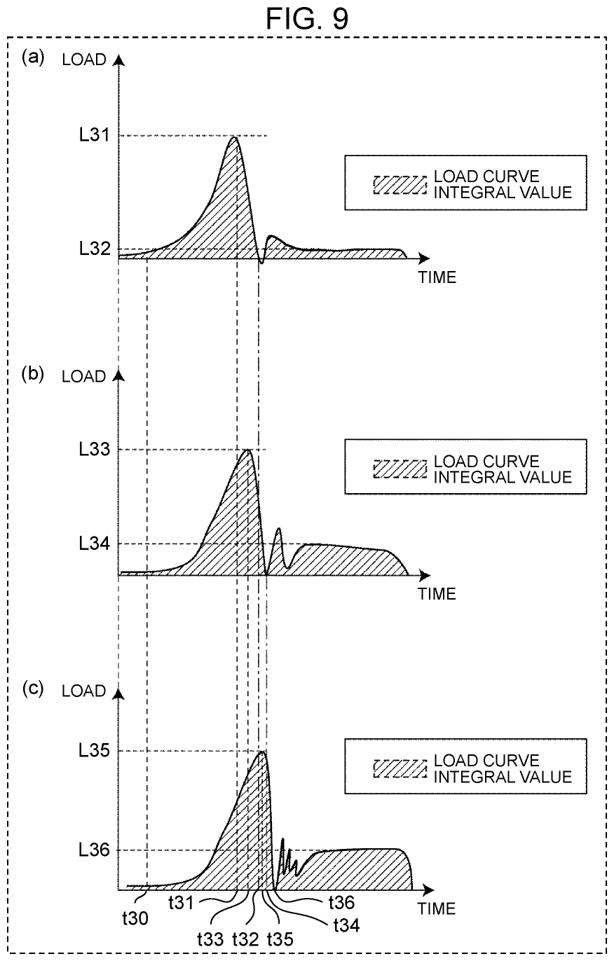

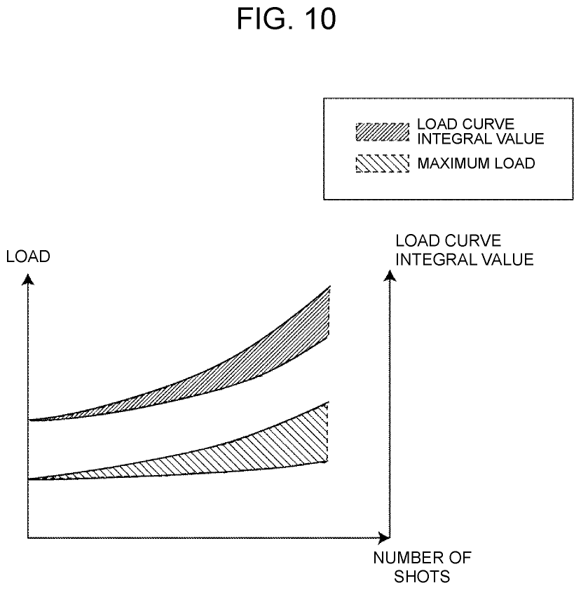

A second exemplary embodiment will be described with reference to FIGS. 9 and 10. The second exemplary embodiment denotes components identical or equivalent to those in the first exemplary embodiment with the same reference marks as those in the first exemplary embodiment. Duplicate description of the first exemplary embodiment will not be described in the second exemplary embodiment.

FIG. 9 is a diagram illustrating a load curve acquired by information acquisition unit 11 of estimation model generation device 100 according to the second exemplary embodiment. Parts (a) to (c) of FIG. 9 show curves that are identical to the load curves of parts (a) to (c) of FIG. 5 described in the first exemplary embodiment, respectively, except that the second exemplary embodiment is different from the first exemplary embodiment in that an estimation model is generated based on integral values of these load curves.

The load curve of part (a) of FIG. 9 shows a maximum load of L31, and a load of L32 to which the load after punching converges. Similarly, the load curve of part (b) of FIG. 9 shows a maximum load of L33, and a load of L34 to which the load after punching converges. Part (c) of FIG. 9 shows a maximum load of L35, and a load of L36 to which the load after punching converges.

The load curves of parts (a) to (c) of FIG. 9 each show time t30 at which punch 31 comes into contact with workpiece 33. The load curve of part (a) of FIG. 9 shows time t31 with maximum load L31, and time t32 at which workpiece 33 is cut. The load curve of part (b) of FIG. 9 similarly shows time t33 with maximum load L33, and time t34 at which workpiece 33 is cut. The load curve of part (c) of FIG. 9 also shows time t35 with maximum load L35, and time t36 at which workpiece 33 is cut.

The present exemplary embodiment causes an estimation model to be generated using integral values of each of the load curves in parts (a) to (b) of FIG. 9.

Parts (a) to (c) of FIG. 9 show respective hatched parts that are each an area of the load curve indicating integral values of the load curve. When the load curve indicates a relationship between loads and time, the integral value of the load curve indicates an impulse of the load applied to the tool (punch 31). When the load curve indicates a relationship between loads and travel distances, the integral value of the load curve indicates energy of the load applied to the tool (punch 31).

The impulse of the load and the energy of the load exhibit substantially equal sensitivity for generating the estimation model. For example, when punch 31 decreases in speed during machining, prediction accuracy is likely to be improved by using the impulse of the load.

The present exemplary embodiment will be described in which a load curve indicates a relationship between a load and a travel distance.

When workpiece 33 is punched by machining device 300, energy applied to the tool (punch 31) for each shot is converted into energy for cutting workpiece 33 and a load on punch 31. Examples of the energy converted into the load on punch 31 include energy causing punch 31 to wear and energy causing distortion to accumulate inside punch 31. Such a load on punch 31 is accumulated in punch 31 as machining is repeated by machining device 300.

FIG. 10 is a graph illustrating a tendency of maximum loads applied to punch 31 and a tendency of integral values (load energy) of a load curve. As illustrated in the graph of FIG. 10, the integral value of the load curve tends to increase as the number of shots increases. The same applies to a case where an impulse is used as the integral value of the load curve. In contrast, the maximum load does not necessarily increase as the number of shots increases.

Thus, generating the estimation model using the integral value of the load curve instead of the maximum load of the load curve enables further improvement in prediction accuracy.

[Effects]

The exemplary embodiment described above enables a load on punch 31 to be captured with higher sensitivity by generating the estimation model using the integral value of the load curve, and thus enabling providing the estimation model generation device and the tool lifetime estimation device that are improved in prediction accuracy.

### Third Exemplary Embodiment

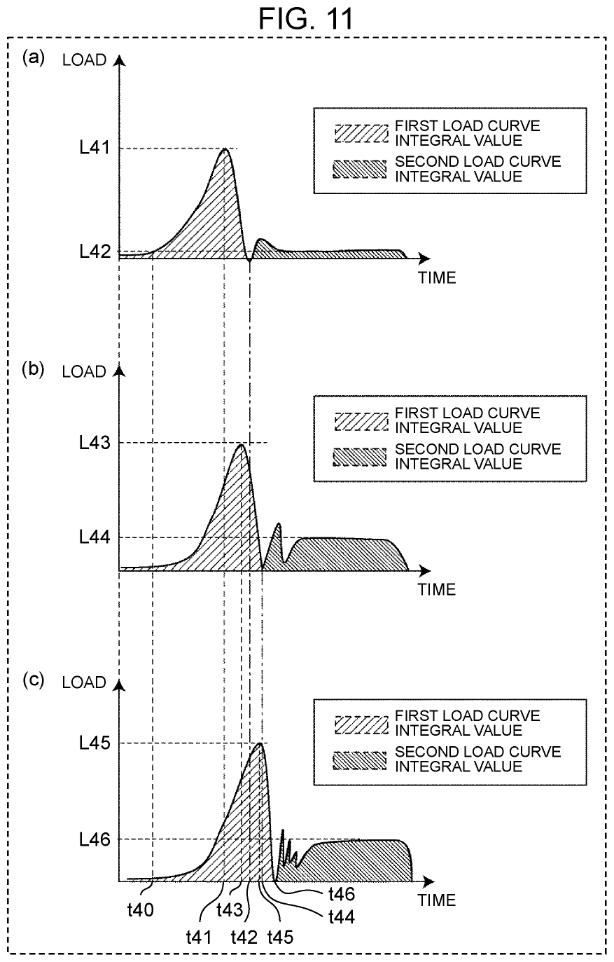

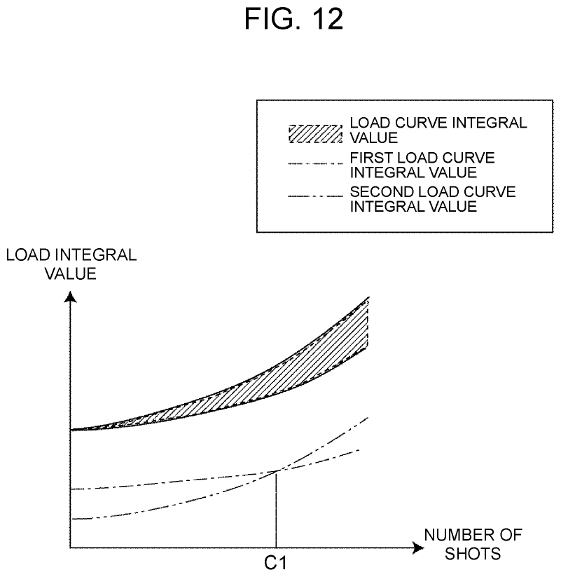

A third exemplary embodiment will be described with reference to FIGS. 11 and 12. The third exemplary embodiment denotes components identical or equivalent to those in the first exemplary embodiment with the same reference marks as those in the first exemplary embodiment. Duplicate description of the first exemplary embodiment will not be described in the third exemplary embodiment.

FIG. 11 is a diagram illustrating a load curve acquired by information acquisition unit 11 of estimation model generation device 100 according to the third exemplary embodiment. Parts (a) to (c) of FIG. 11 show curves that are identical to the load curves of parts (a) to (c) of FIG. 5 described in the first exemplary embodiment, respectively. The third exemplary embodiment is different from the first exemplary embodiment in that estimation model generation unit 12 generates an estimation model based on load data obtained by separating the load curves above into a first load curve during deformation of workpiece 33 and a second load curve immediately after the deformation of the workpiece. The term, during deformation, means a period from a start of the deformation to completion of the deformation. The term, immediately after deformation, means a predetermined period from the completion of the deformation.

The load curve of part (a) of FIG. 11 shows a maximum load of L41, and a load of L42 to which the load after punching converges. Similarly, the load curve of part (b) of FIG. 11 shows a maximum load of L43, and a load of L44 to which the load after punching converges. Part (c) of FIG. 11 shows a maximum load of L45, and a load of L46 to which the load after punching converges.

The load curves of parts (a) to (c) of FIG. 11 each show time t40 at which punch 31 comes into contact with workpiece 33. The load curve of part (a) of FIG. 11 shows time t41 with maximum load L41, and time t42 at which workpiece 33 is cut. The load curve of part (b) of FIG. 11 similarly shows time t43 with maximum load L43, and time t44 at which workpiece 33 is cut. The load curve of part (c) of FIG. 11 also shows time t45 with maximum load L45, and time t46 at which workpiece 33 is cut.

The present exemplary embodiment causes the estimation model to be generated using the first load curve and the second load curve obtained by dividing the load curve into two curves before and after workpiece 33 is cut (before and after each of time t42, time t44, and time t46).

The first load curve is obtained by extracting parts corresponding to sections S1 and S2 in FIG. 3. That is, the first load curve is from when punch 31 starts to descend to when workpiece 33 is cut (FIG. 2C). The second load curve is obtained by extracting a part corresponding to section S3 in FIG. 3. That is, the second load curve is after workpiece 33 is cut (FIG. 2D).

The present exemplary embodiment causes load data to be generated based on an integral value of the first load curve and an integral value of the second load curve.

FIG. 12 is a graph illustrating a tendency of integral values of load energy of the entire load curve, and a tendency of integral values of load energy of each of the first load curve and the second load curve. The graph of FIG. 12 reveals that the first load curve and the second load curve each have a different tendency to increase in the number of shots. For example, the graph of FIG. 12 shows the first load curve and the second load curve that are reversed in integral value at the number of shots C1. This graph indicates that the first load curve has an integral value larger than that of the second load curve by the number of shots C1, and thus workpiece 33 during deformation receives more energy. Similarly, this graph indicates that the second load curve has an integral value larger than that of the first load curve after the number of shots C1, and thus workpiece 33 immediately after the deformation receives more energy.

Thus, estimation model generation unit 12 may generate the estimation model using load data acquired by weighting the first load curve and the second load curve. For example, weighted load data can be generated by multiplying the first load curve and the second load curve by a first coefficient and a second coefficient, respectively.

Preferable examples of the coefficient when workpiece 33 is made of a material having high hardness include a coefficient set to 1.0 for the first load curve and a coefficient set between 0.1 and 1.0 inclusive for the second load curve. When workpiece 33 is made of a material having high hardness and is punched out, a ratio of energy for cutting workpiece 33 increases in energy applied to punch 31 for each shot. Thus, the coefficient for the first load curve may be increased.

When workpiece 33 is made of a material having a large elongation such as Al or Cu, when multiple layers are collectively punched out, or the like, a coefficient is preferably set more than or equal to 0.1 and less than 1.0 for the first load curve, and a coefficient is preferably set to 1.0 for the second load curve. In this case, load energy is applied to punch 31 when workpiece 33 is drawn into punch 31 after cutting to cause a side surface of punch 31 to interfere with workpiece 33, the load energy increasing more than energy for cutting the workpiece 33.

When punch 31 and die 32 have a small clearance therebetween, or when the workpiece has a thin plate thickness, a coefficient more than or equal to 0.1 and less than 1.0 is preferably set for the first load curve, and a coefficient of 1.0 is preferably set for the second load curve. The small clearance between punch 31 and die 32 means that the clearance is approximately less than or equal to 10 μm. The thin plate thickness of workpiece 33 means that the plate thickness is approximately less than or equal to 150 μm. In general, the plate thickness of workpiece 33 and the clearance between punch 31 and die 32 are in a proportional relationship. Even in this case, the coefficient for the first load curve is preferably more than or equal to 0.1 and less than 1.0, and the coefficient for the second load curve is preferably 1.0. This is because a small clearance between punch 31 and die 32 causes a cumulative tolerance such as machining accuracy of punch 31 and die 32 or assembling accuracy of punch 31 and die 32 to be close to the clearance, and causes the side surface of punch 31 to be likely to interfere with a material.

[Effects]

The exemplary embodiment described above enables generating the estimation model based on the load data obtained by separating the load curve into the first load curve and the second load curve, and thus enabling providing the estimation model generation device and the tool lifetime estimation device that have higher prediction accuracy.

Depending on a tool, machining conditions, or the like of the machining device, increase of a load on punch 31 varies between during deformation of a workpiece and immediately after deformation of the workpiece. Thus, separating the load curve during deformation of the workpiece and immediately after the deformation of the workpiece enables fine tuning for each tool of the machining device or for each machining condition. The prediction accuracy accordingly can be further improved.

### Fourth Exemplary Embodiment

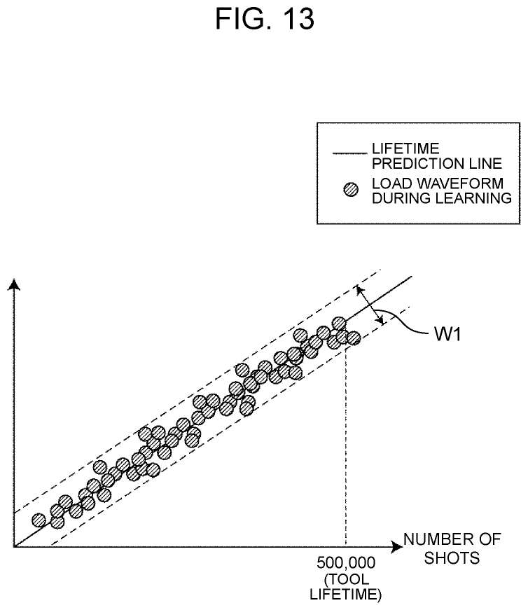

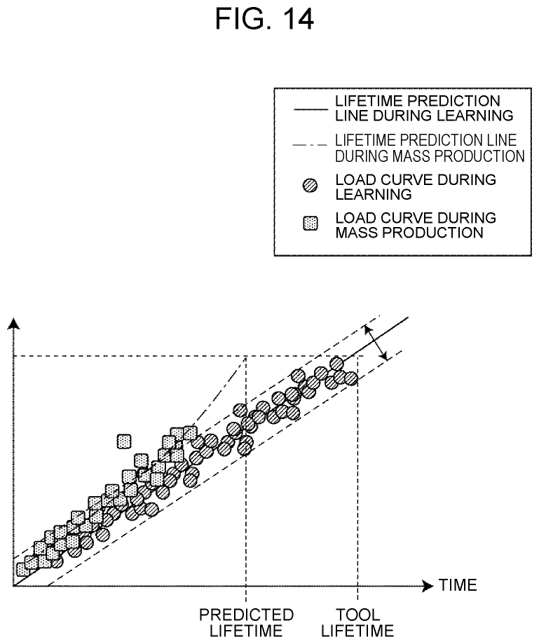

A fourth exemplary embodiment will be described with reference to FIGS. 13 and 14. The fourth exemplary embodiment denotes components identical or equivalent to those in the first exemplary embodiment with the same reference marks as those in the first exemplary embodiment. Duplicate description of the first exemplary embodiment will not be described in the fourth exemplary embodiment. FIG. 13 is a graph illustrating a relationship between a load curve and the number of shots. FIG. 14 is a graph illustrating estimation of a tool lifetime using the graph of FIG. 13.

The fourth exemplary embodiment is different from the first exemplary embodiment in that estimation model generation unit 12 generates an estimation model by performing machine learning using teacher data in which the load curve as an explanatory variable is associated with the tool lifetime as a target variable.

For example, data on machining device 300 including punch 31 that reaches the tool lifetime in 500,000 shots is used as the teacher data. In this case, the explanatory variable is the load curve illustrated in each of parts (a) to (c) of FIG. 5, and the target variable is the number of shots from the acquisition of the load curve to the tool lifetime (500,000 shots).

Estimation model generation unit 12 of estimation model generation device 100 performs machine learning using data as teacher data, in which a load curve as an explanatory variable is associated with the number of shots up to the tool lifetime as a target variable. As a result of the machine learning, the relationship between the load curve and the number of shots is shown in the graph of FIG. 13. The graph of FIG. 13 shows features of respective load curves, the features being extracted as respective numerical values, for example, and the load curves are each associated with the number of shots when acquired. A lifetime prediction line can be derived from the graph of FIG. 13. The lifetime prediction line may be provided with deflection width Wi illustrated in FIG. 13 depending on a variation of the load curve or a frequency of learning.

The machine learning preferably uses a load curve with few abnormal phenomena. That is, the machine learning preferably uses a load curve for a series of machining repeated without causing as much abnormality as possible from a start of use of punch 31 to a lifetime of punch 31. Alternatively, learning of a series of repeated load curves from the start of the machining to the lifetime of punch 31 may be repeated multiple times. This case enables increase in absolute number of load curves to be learned, and thus enabling decrease in influence of a load curve on a learning result when abnormality occurs.

Available examples of an algorithm of the machine learning include a neural network. Using the neural network enables generating an estimation model that predicts a relationship between a waveform of a load curve and a tool lifetime by processing the load curve as an image to extract a feature of the load curve.

When the teacher data is time-series data as in the present embodiment, prediction accuracy can be further improved by using a recurrent NN (RNN).

Estimation unit 22 of the tool lifetime estimation device estimates a tool lifetime based on a load curve during actual machining such as during mass production. For example, when a load curve similar in characteristics to that appeared at a 300,000-th shot during learning appears at a 200,000-th shot during mass production, punch 31 during mass production can be estimated to be shorter in lifetime than punch 31 during learning. As illustrated in FIG. 14, estimation unit 22 estimates a remaining lifetime (allowable number of shots) of punch 31 during current machining from a load curve acquired during mass production.

[Effects]

The exemplary embodiment described above enables providing an estimation model generation device and a tool lifetime estimation device that are improved in prediction accuracy of a tool lifetime.

Although an example is described in which estimation model generation unit 12 generates an estimation model by performing machine learning using a load curve with few abnormal phenomena in the exemplary embodiment described above, data used for machine learning is not limited thereto. For example, the machine learning may be repeated using a load curve serving as a reference with few abnormal phenomenon and a load curve for punch 31 with a short lifetime. This enables generating an estimation model with higher prediction accuracy.

Then, input data may include not only teacher data in which a load curve and a tool lifetime are associated with each other, but also data including information such as information on material of a workpiece, machining conditions, tool conditions, or the like. Examples of the information on material includes a material of the workpiece, a thickness of the workpiece, a height of the workpiece, an elongation of the workpiece, and the number of workpieces. Examples of the machining conditions include the number of shots, a travel distance of punch 31, operation time of punch 31, and operation speed of punch 31. Examples of the tool conditions include a clearance between punch 31 and die 32, materials of punch 31 and die 32, a circumferential length of punch 31, a shape of punch 31, and a coating material of punch 31.

### Fifth Exemplary Embodiment

A fifth exemplary embodiment will be described. The fifth exemplary embodiment denotes components identical or equivalent to those in the fourth exemplary embodiment with the same reference marks as those in the fourth exemplary embodiment. Duplicate description of the fourth exemplary embodiment will not be described in the fifth exemplary embodiment.

The fifth exemplary embodiment is different from the fourth exemplary embodiment in that teacher data is used in which an integral value of a load curve as an explanatory variable is associated with a tool lifetime as a target variable.

Estimation model generation unit 12 in the present exemplary embodiment generates an estimation model by performing machine learning using teacher data in which integral values of respective load curves as shown in part (a) to part (c) of FIG. 9 as explanatory variables are each associated with a tool lifetime as a target variable.

Using the integral value of the load curve instead of the load curve during machine learning enables a load on punch 31 to be sensed with higher sensitivity.

[Effects]

The exemplary embodiment described above enables providing an estimation model generation device and a tool lifetime estimation device that are improved more in prediction accuracy.

### Sixth Exemplary Embodiment

A sixth exemplary embodiment will be described. The sixth exemplary embodiment denotes components identical or equivalent to those in the fourth exemplary embodiment with the same reference marks as those in the fourth exemplary embodiment. Duplicate description of the fourth exemplary embodiment will not be described in the sixth exemplary embodiment.

The present exemplary embodiment is different from the fourth exemplary embodiment in that estimation model generation unit 12 uses load data as an explanatory variable, the load data being generated based on an integral value of a first load curve and an integral value of a second load curve, as shown in part (a) to part (c) of FIG. 11.

Performing machine learning using integral values of the first load curve and the second load curve into which the load curve is divided enables a load on punch 31 to be sensed with higher sensitivity.

[Effects]

The exemplary embodiment described above enables providing an estimation model generation device and a tool lifetime estimation device that are improved more in prediction accuracy.

### INDUSTRIAL APPLICABILITY

The estimation model generation device and the tool lifetime estimation device according to the present disclosure are widely applicable to tool lifetime prediction in a machining device that performs machining such as cutting, bending, or drawing.

### REFERENCE MARKS IN THE DRAWINGS

11 information acquisition unit
12 estimation model generation unit
13 storage unit
21 information acquisition unit
22 estimation unit
23 storage unit
31 punch
32 die
33 workpiece
34 sensor
100 estimation model generation device
200 tool lifetime estimation device
300 machining device

1. An estimation model generation device configured to generate an estimation model for estimating a lifetime of a tool based on a load curve indicating temporal change or positional change of the load applied to the tool, the tool being used for repeatedly machining a plurality of workpieces in a plate-shape while applying the load to each of the plurality of workpieces, the estimation model generation device comprising:
an information acquisition unit that acquires the load curve at a timing before the tool reaches a lifetime due to repeated machining using the tool;
an estimation model generation unit that generates, based on load data and a tool lifetime, an estimation model for predicting the lifetime of the tool, the load data being obtained by separating the load curve into a first load curve and a second load curve, the tool lifetime being a time period from time of acquiring the load curve to time at which the tool reaches the lifetime; and
a storage unit that stores the estimation model, wherein
the first load curve is a load curve when the workpiece is deformed due to machining with the tool, and
the second load curve is a load curve immediately after the workpiece is deformed due to machining with the tool.

2. The estimation model generation device according to claim 1, wherein the load data is generated based on an integral value of the first load curve and an integral value of the second load curve.

3. The estimation model generation device according to claim 1, wherein the estimation model generation unit generates the estimation model by performing machine learning using teacher data in which the load data as an explanatory variable is associated with the tool lifetime as a target variable.

4. The estimation model generation device according to claim 1, wherein the estimation model generation unit generates the estimation model using the load data acquired by weighting the first load curve and the second load curve.

5. The estimation model generation device according to claim 4, wherein the first load curve and the second load curve are weighted by multiplying the first load curve and the second load curve by a first coefficient and a second coefficient, respectively.

6. The estimation model generation device according to claim 1, wherein the load curve indicates a relationship between a load applied to the tool and time.

7. The estimation model generation device according to claim 1, wherein the load curve indicates a relationship between a load applied to the tool and a travel distance of the tool.

8. A tool lifetime estimation device configured to generate an estimation model for estimating a lifetime of a tool based on a load curve indicating temporal change or positional change of the load applied to the tool, the tool being used for repeatedly machining a plurality of workpieces in a plate-shape while applying the load to each of the plurality of workpieces, the tool lifetime estimation device comprising:
a storage unit that stores the estimation model generated by the estimation model generation device according to claim 1;
an information acquisition unit that acquire a load curve during machining with the tool;
a load data generator that generates load data in which the load curve during machining is separated into a first load curve and a second load curve; and
an estimation unit that estimates the tool lifetime from the load data based on the estimation model, wherein
the first load curve is a load curve when the workpiece is deformed due to machining with the tool, and
the second load curve is a load curve immediately after the workpiece is deformed due to machining with the tool.

9. The tool lifetime estimation device according to claim 8, wherein the load data is generated based on an integral value of the first load curve and an integral value of the second load curve.
